(19) United States
(12) Patent Application Publication
(10) Pub. No.: US 2014/0092636 A1
(43) Pub. Date: Apr. 3, 2014

(54) COMPOUND SEMICONDUCTOR DEVICE AND METHOD OF MANUFACTURING THE SAME

(71) Applicants: FUJITSU LIMITED, KAWASAKI-SHI (JP); FUJITSU SEMICONDUCTOR LIMITED, YOKOHAMA-SHI (JP)

(72) Inventors: Masahito Kanamura, Isehara (JP); Jun YOSHIKI, Aizuwakamatsu (JP)

(73) Assignees: FUJITSU SEMICONDUCTOR LIMITED, YOKOHAMA-SHI (JP); FUJITSU LIMITED, KAWASAKI-SHI (JP)

(21) Appl. No.: 13/975,713

(22) Filed: Aug. 26, 2013

(30) Foreign Application Priority Data
Sep. 28, 2012 (JP) 2012-217622

(51) Int. Cl. H01L 29/43; H02M 3/28; H01L 29/40

(52) U.S. Cl. CPC H01L 29/435; H01L 29/401; H02M 3/28
USPC 363/17; 257/192; 438/573

(57) ABSTRACT

A gate electrode is formed above a compound semiconductor stacked structure, and the gate electrode includes a stack of a TaN:Al layer in which Al is solid-dissolved in TaN, a TaAlN layer made of a compound of TaN and Al, and an Al layer.

### CROSS-REFERENCE TO RELATED APPLICATION

This application is based upon and claims the benefit of priority of the prior Japanese Patent Application No. 2012-217622, filed on Sep. 28, 2012, the entire contents of which are incorporated herein by reference.

### FIELD

The embodiments discussed herein are directed to a compound semiconductor device and a method of manufacturing the same.

### BACKGROUND

Applying nitride semiconductors to high-withstand-voltage and high-power semiconductor devices by utilizing their characteristics such as a high saturation electron velocity and a wide band gap has been considered. For example, GaN being a nitride semiconductor has a band gap of 3.4 eV, which is wider than a band gap of Si (1.1 eV) and a band gap of GaAs (1.4 eV), and has high breakdown electric field intensity. This makes GaN very promising as a material of semiconductor devices for power supply realizing a high voltage operation and a high power.

Many reports have been made on field-effect transistors, in particular, HEMTs (High Electron Mobility Transistors) as semiconductor devices using nitride semiconductors. For example, among GaN-based HEMTs (GaN-HEMTs), an AlGaN/GaN HEMT using GaN as an electron transit layer and using AlGaN as an electron supply layer has been drawing attention. In the AlGaN/GaN HEMT, a distortion ascribable to a difference in lattice constant between GaN and AlGaN occurs in AlGaN. Owing to piezoelectric polarization caused by the distortion and spontaneous polarization of AlGaN, high-concentration two-dimensional electron gas (2DEG) is obtained. Therefore, the AlGaN/GaN HEMT is expected as a high-efficiency switch element or a high-withstand-voltage power device for electric vehicles and the like.
[Patent Document 1] Japanese Laid-open Patent Publication No. 2006-302999

As described above, an electronic device using a GaN layer as an electron transit layer, for instance, is greatly expected to have a stable operation under a high-voltage and high-temperature environment, but has problems to be solved. In particular, the most important task for its practical application is to establish high reliability under a high temperature and a high voltage. Under the high temperature and the high voltage, there is a concern about deterioration of various kinds of electrodes included in a transistor. The occurrence of the deterioration of a gate electrode especially has a great influence on a withstand voltage characteristic and a threshold characteristic. Under such circumstances, a development of a gate electrode structure having high reliability is currently waited for.

### SUMMARY

A compound semiconductor device according to an aspect includes: a compound semiconductor stacked structure; and an electrode formed above the compound semiconductor stacked structure, the electrode including: a first electrode layer having a first low-resistance metal; and a second electrode layer disposed between the compound semiconductor stacked structure and the first electrode layer and having a first nitride conductor in which a second low-resistance metal is solid-dissolved.

A method of manufacturing a compound semiconductor device according to an aspect includes: forming a compound semiconductor stacked structure; and forming an electrode above the compound semiconductor stacked structure, the electrode including: a first electrode layer having a first low-resistance metal; and a second electrode layer disposed between the compound semiconductor stacked structure and the first electrode layer and having a first nitride conductor in which a second low-resistance metal is solid-dissolved.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A and FIG. 1B are cross-sectional views illustrating a schematic structure of a comparative example of an AlGaN/GaN HEIST.

FIG. 2A and FIG. 2B are schematic cross-sectional views illustrating examples of various forms of the AlGaN/GaN HEMT.

FIG. 3A to FIG. 3C are schematic cross-sectional views illustrating a method of manufacturing an AlGaN/GaN HEMT according to a first embodiment in order of steps.

FIG. 4A to FIG. 4C, which are continued from FIG. 3A to FIG. 3C, are schematic cross-sectional views illustrating the method of manufacturing the AlGaN/GaN HEMT according to the first embodiment in order of steps.

FIG. 5A and FIG. 5B, which are continued from FIG. 4A to FIG. 4C, are schematic cross-sectional views illustrating the method of manufacturing the AlGaN/GaN HEMT according to the first embodiment in order of steps.

FIG. 6 is a characteristic chart representing changes in a threshold voltage when a power-on test is conducted under a 200° C. environment with a gate voltage set to −10 V and a drain voltage set to 200 V.

FIG. 7 is a characteristic chart representing changes in a gate leakage current when a power-on test is conducted at 200° C. with a gate-drain voltage set to 200 V.

FIG. 8A to FIG. 8C are schematic cross-sectional views illustrating main steps of a method of manufacturing an AlGaN/GaN HEMT according to a second embodiment.

FIG. 9 is a connection diagram illustrating a schematic structure of a power supply circuit according to a third embodiment.

FIG. 10 is a connection diagram illustrating a schematic structure of a high-frequency amplifier according to a fourth embodiment.

### DESCRIPTION OF EMBODIMENTS

First, examples of various forms of a compound semiconductor device will be described based on comparison with a comparative example. As the compound semiconductor device, an AlGaN/GaN HEMT of a nitride semiconductor is disclosed.

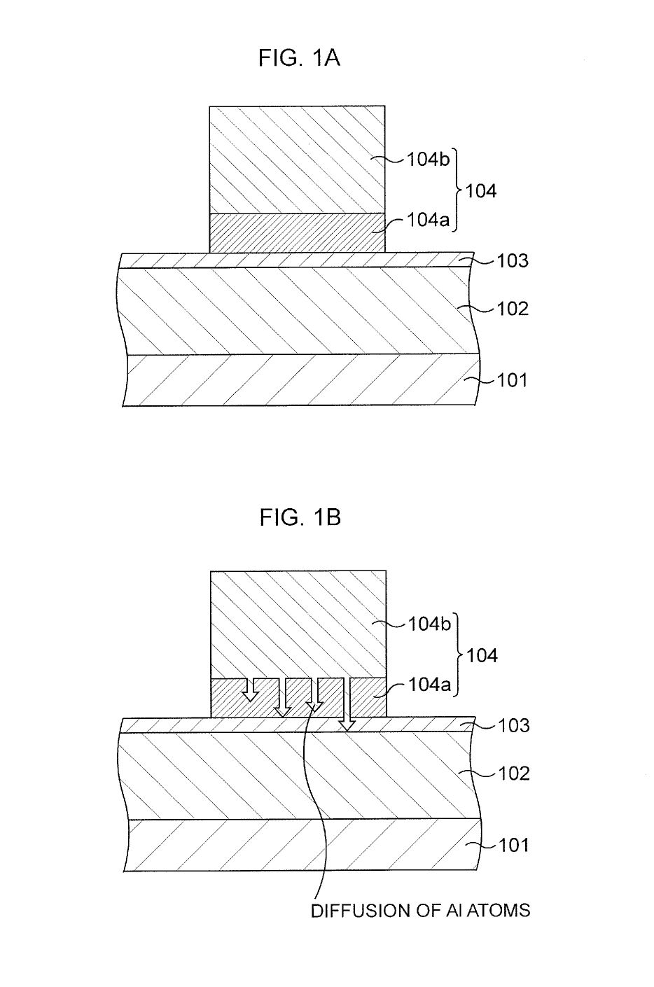

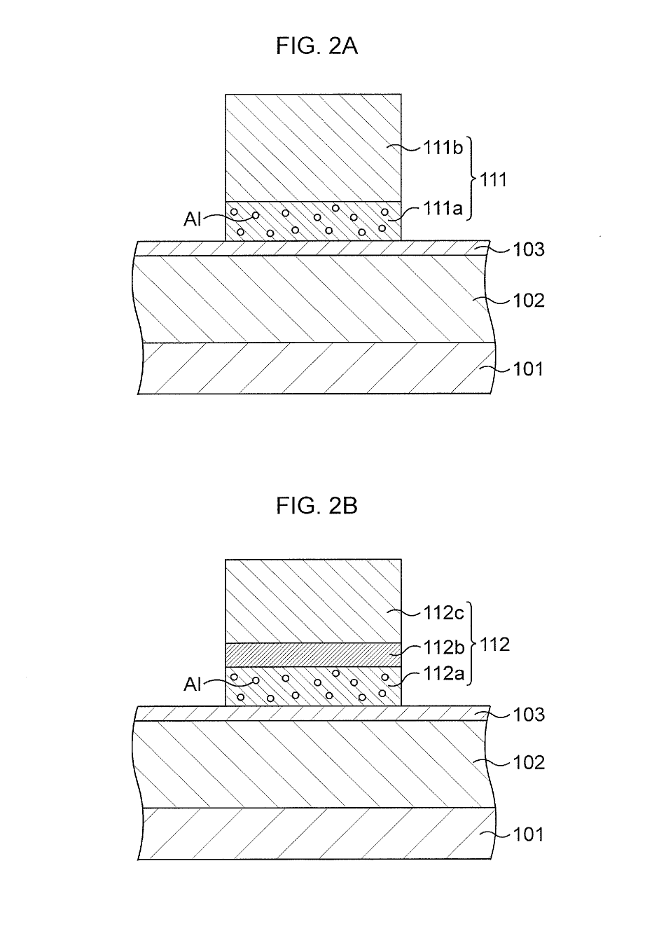

FIG. 1A and FIG. 1B are cross-sectional views illustrating a schematic structure of the AlGaN/GaN HEMT of the comparative example, FIG. 1A illustrating a state before energization and FIG. 1B illustrating a state after the energization. FIG. 2A and FIG. 2B are schematic cross-sectional views illustrating examples of various forms of the AlGaN/GaN HEMT, FIG. 2A illustrating a first form example and FIG. 2B illustrating a second form example. In FIG. 2A and FIG. 2B, the same constituent members and so on as those in FIG. 1A and FIG. 1B are denoted by the same reference signs and a description thereof will be omitted.

In the AlGaN/GaN HEMT of a MIS type according to the comparative example, a compound semiconductor stacked structure 102 is formed on a Si substrate 101, and a gate electrode 104 is formed on the compound semiconductor stacked structure 102 via a gate insulating film 103, as illustrated in FIG. 1A. As will be described in later-described embodiments, the compound semiconductor stacked structure 102 is a structure in which an electron transit layer of GaN, an electron supply layer of AlGaN, and so on are stacked. The gate electrode 104 is composed of a stack of, for example, a TaN layer 104a with an about 40 nm thickness and an Al layer 104b with an about 400 nm thickness. On the compound semiconductor stacked structure 2, a source electrode and a drain electrode are formed on both sides of the gate electrode 104 but their illustration is omitted.

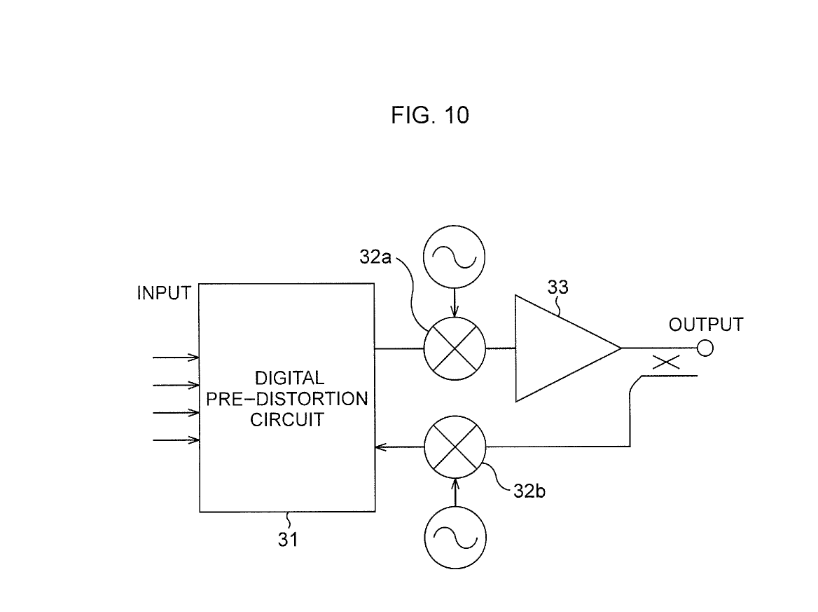

In the AlGaN/GaN HEMT of the comparative example, as a result of a power-on test under a high-temperature and high-voltage environment, Al atoms of the Al layer 104b diffuse downward in the TaN layer 104a in the gate electrode 104 as illustrated in FIG. 10. The TaN layer 104a is formed in a polycrystalline state or an amorphous state. This is thought to be why the energization under the high-temperature and high-voltage environment causes the Al atoms to permeate to grain boundaries of the TaN layer 104a to diffuse. In this case, in the extreme case, the Al atoms diffuse into the gate insulating film 103. Consequently, a change in a threshold voltage and an increase in a gate leakage current are seen.

In the above-described comparative example, the MIS-type structure in which the gate insulating film is provided between the gate electrode and the compound semiconductor stacked structure is illustrated as an example. In a Schottky-type AlGaN/GaN HEMT in which, without a gate insulating film, a gate electrode is in contact with a compound semiconductor stacked structure, Al atoms of an Al layer go beyond a TaN layer to permeate to the compound semiconductor stacked structure. Consequently, a change in a threshold voltage and an increase in a gate leakage current are greater than in the MIS-type structure.

In the MIS-type AlGaN/GaN HEMT according to the first form example, a gate electrode 111 is formed on a compound semiconductor stacked structure 102 via a gate insulating film 103 as illustrated in FIG. 2A. The gate electrode ill is composed of a stack of, for example, a TaN:Al layer 111a with an about 40 nm thickness and an Al layer 111b with an about 400 nm thickness. The Al layer 111b is a first electrode layer having a first low-resistance metal and the TaN:Al layer 111a is a second electrode layer having a first nitride conductor in which a second low-resistance metal is solid-dissolved.

The first and second low-resistance metals are each at least one kind selected from Al and Cu. A metal element forming the first nitride conductor is at least one kind selected from Ta, Ti, and W. In the first form example, a case where the first and second low-resistance metals are both Al and the first nitride conductor is TaN is exemplified. Besides this combination, there are a case where one of the first and second low-resistance metals is Al and the other is Cu, a case where the both are Cu, and so on. There are a case where the first nitride conductor is TiN or WN, and so on.

The first form example adopts a structure in which in the TaN:Al layer 111a, Al is solid-dissolved in TaN and Al fills grain boundaries. With this structure, even when dower is on under a high-temperature and high-voltage environment, Al trying to diffuse downward from the Al layer 111a is blocked by the TaN:Al layer 111a, so that the downward diffusion of Al is inhibited. Consequently, a threshold voltage is stabilized and a gate leakage current is greatly reduced.

In the MIS-type AlGaN/GaN HEMT according to the second form example, a gate electrode 112 is formed on a compound semiconductor stacked structure 102 via a gate insulating film 103 as illustrated in FIG. 2B. The gate electrode 112 is composed of a stack of, for example, a TaN:Al layer 112a with an about 40 nm thickness, a TaAlN layer 112b with an about 20 nm thickness, and an Al layer 112c with an about 400 nm thickness. The Al layer 112c is a first electrode layer having a first low-resistance metal and the TaN:Al layer 112a is a second electrode layer having a first nitride conductor in which a second low-resistance metal is solid-dissolved. The TaAlN layer 112b interposed between the TaN:Al layer 112a and the Al layer 112c is a third electrode layer having a compound of a second nitride conductor and a third low-resistance metal.

The first, second, and third low-resistance metals are each at least one kind selected from Al and Cu. Metal elements forming the first and second nitride conductors are each at least one kind selected from Ta, Ti, and W. In the second form example, a case where the first, second, and third low-resistance metals are all Al and the first and second nitride conductors are both TaN is exemplified. Besides this combination, there are a case where one of the first, second, and third low-resistance metals is Al and the other two are Cu, a case where one of them is Cu and the other two are Al, and a case where all of them are Cu, and so on. As for the first and second nitride conductors, when the both are different, there is a case where they are each one kind selected from TaN, TiN, and WN, and when the both are the same, there are a case where they are TiN or WN, and so forth.

In the second form example, the TaN:Al layer 112a adopts a structure in which Al is solid-dissolved in TaN, and Al fills grain boundaries. The TaAlN layer 112b adopts a structure of being made of a compound of TaN and Al. This two-layer structure more surely prevents the downward diffusion of Al. That is, even when power is on under a high-temperature and high-voltage environment, Al trying to diffuse downward from the Al layer 112c is blocked by the TaAlN layer 112b and the TaN:Al layer 112a, so that the downward diffusion of Al is inhibited. Consequently, a threshold voltage is stabilized and gate leakage current greatly reduces.

### First Embodiment

In this embodiment, a MIS-type AlGaN/GaN HEMT is disclosed as the compound semiconductor device.

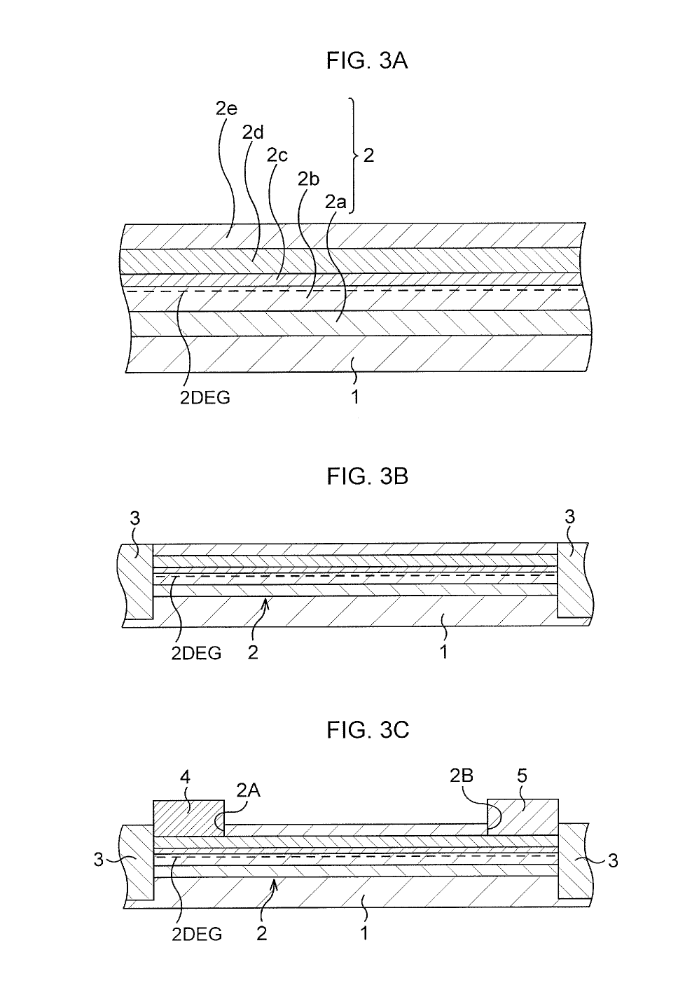

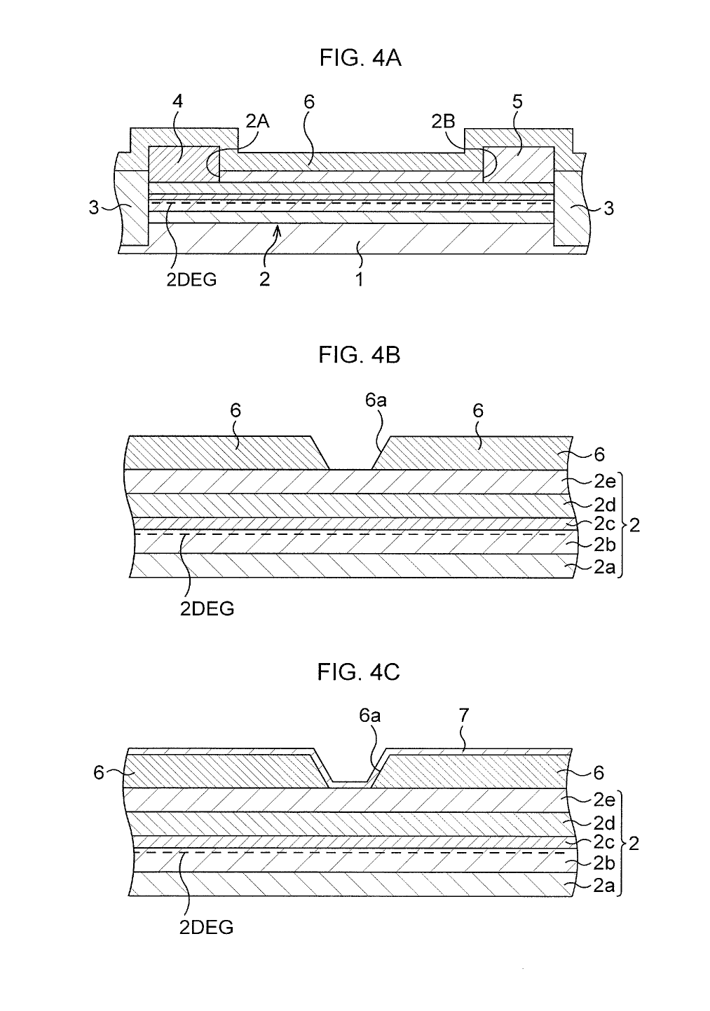

FIG. 3A to FIG. 5B are schematic cross-sectional views illustrating a method of manufacturing the AlGaN/GaN HEMT according to the first embodiment in order of steps. Note that, from FIG. 4B onward, the vicinity of an electrode recess of a protective insulating film is illustrated in an enlarged manner, and the illustration of a Si substrate, element isolation structures, a source electrode, and a drain electrode is omitted.

First, as illustrated in FIG. 3A, a compound semiconductor stacked structure 2 is formed on, for example, a Si substrate 1 as a growth substrate. As the growth substrate, a SiC substrate, a sapphire substrate, a GaAs substrate, a GaN substrate, or the like may be used instead of the Si substrate. Conductivity of the substrate may be either semi-insulating or conductive.

The compound semiconductor stacked structure 2 includes a buffer layer 2a, an electron transit layer 2b, an intermediate layer 2c, an electron supply layer 2d, and a cap layer 2e.

In the finished AlGaN/GaN HEMT, two-dimensional electron gas (2DEG) is generated in the vicinity of an interface, of the electron transit layer 2b, with the electron supply layer 2d (to be exact, the intermediate layer 2c) during its operation. This 2DEG is generated based on a difference in lattice constant between a compound semiconductor (here GaN) of the electron transit layer 2b and a compound semiconductor (here AlGaN) of the electron supply layer 2d.

In more detail, on the Si substrate 1, the following compound semiconductors are grown by, for example, a MOVPE (Metal Organic Vapor Phase Epitaxy) method. A MBE (Molecular Beam Epitaxy) method or the like may be used instead of the MOVPE method.

On the Si substrate 1, AlN with an about 5 nm thickness, an i (intentionally undoped)-GaN with an about 1 μm thickness, an i-AlGaN with an about 5 nm thickness, an n-AlGaN with an about 30 nm thickness, and n-GaN with an about 3 nm thickness are sequentially grown. Consequently, the buffer layer 2a, the electron transit layer 2b, the intermediate layer 2c, the electron supply layer 2d, and the cap layer 2e are formed. As the buffer layer 2a, a stacked structure or a superlattice structure of materials selected from AlN, AlGaN, and GaN may be used instead of the AlN single layer.

As a growth condition of AlN, mixed gas of trimethylaluminum (TMA) gas and ammonia (NH₃) gas is used as source gas. As a growth condition of GaN, mixed gas of trimethylgallium (TMG) gas and NH₃ gas is used as source gas. As a growth condition of AlGaN, mixed gas of TMA gas, TMG gas, and NH₃ gas is used as source gas. Depending on the compound semiconductor layer that is to be grown, whether or not to supply the TMA gas being an Al source and the TMG gas being a Ga source and their flow rates are appropriately set. A flow rate of the NH₃ gas being a common source is set to about 100 ccm to about 10 LM. Further, growth pressure is set to about 50 Torr to about 300 Torr, and growth temperature is set to about 1000° C.; to about 1200° C.

In order to grow GaN and AlGaN as an n-type, that is, in order to grow n-GaN of the cap layer 2e and n-AlGaN of the electron supply layer 2d, for example, SiH₄ gas containing, for instance, Si is added as n-type impurities to the source gas at a predetermined flow rate. Consequently, GaN and AlGaN are doped with Si. A doping concentration of Si is set to about 1×10¹⁸/cm³ to about 1×10²⁰/cm³, for example, set to about 5×10¹⁸/cm³.

Subsequently, element isolation structures 3 are formed as illustrated in FIG. 3B. From FIG. 4A onward, the illustration of the element isolation structures 3 is omitted.

In more detail, argon (Ar), for instance, is injected to element isolation regions of the compound semiconductor stacked structure 2. Consequently, the element isolation structures 3 are formed in the compound semiconductor stacked structure 2. The element isolation structures 3 demarcate an active region on the compound semiconductor stacked structure 2.

Incidentally, instead of the above injection method, a STI (Shallow Trench Isolation) method, for instance, may be used for the element isolation. At this time, chlorine-based etching gas, for instance, is used for dry-etching of the compound semiconductor stacked structure 2.

Subsequently, as illustrated in FIG. 3C, a source electrode 4 and a drain electrode 5 are formed.

In more detail, first, electrode recesses 2A, 2B are formed at positions where to form the source electrode and the drain electrode (planned electrode formation positions), in a surface of the compound semiconductor stacked structure 2.

A resist is applied on the surface of the compound semiconductor stacked structure 2. The resist is processed by lithography, whereby openings from which portions corresponding to the planned electrode formation positions, in the surface of the compound semiconductor stacked structure 2 are exposed are formed in the resist. Consequently, a resist mask having the openings is formed.

By using this resist mask, the planned electrode formation positions of the cap layer. 2e are dry-etched to be removed until a surface of the electron supply layer 2d is exposed. Consequently, the electrode recesses 2A, 2B from which the planned electrode formation positions of the surface of the electrode supply layer 2d are exposed are formed. As an etching condition, inert gas such as Ar and chlorine-based gas such as Cl₂ are used as etching gas, and for example, a flow rate of Cl₂ is set to 30 sccm, a pressure is set to 2 Pa, and a RF supply power is set to 20 W. Incidentally, in forming the electrode recesses 2A, 2B, the etching may be performed up to the middle of the cap layer 2e or up to the electron supply layer 2d or further.

The resist mask is removed by ashing or the like.

A resist mask for forming the source electrode and the drain electrode is formed. Here, an eaves-structure two-layer resist suitable for a vapor deposition method and a liftoff method is used, for instance. This resist is applied on the compound semiconductor stacked structure 2, and openings from which the electrode recesses 2A, 2B are exposed are formed. Consequently, the resist mask having the openings is formed.

By using this resist mask, Ta/Al, for example, is deposited as an electrode material on the resist mask including the inside of the openings from which the electrode recesses 2A, 2B are exposed, by, for example, the vapor deposition method. A thickness of Ta is about 20 nm and a thickness of Al is about 200 nm. The resist mask and Ta/Al deposited thereon are removed by the liftoff method. Thereafter, the Si substrate 1 is heat-treated, for example, in a nitrogen atmosphere at a temperature of about 400° C. to about 1000° C., for example, about 600° C., and the residual Ta/Al is brought into ohmic contact with the electron supply layer 2d. The heat treatment is not sometimes necessary, provided that the ohmic contact of Ta/Al and the electron supply layer 2d is obtained. Consequently, the source electrode 4 and the drain electrode 5 part of whose the electrode material fills the electrode recesses 2A, 2B are formed.

Subsequently, as illustrated in FIG. 4A, a protective insulating film 6 is formed.

In more detail, a silicon nitride (SiN) with an about 30 nm to about 500 nm thickness, for example, an about 200 nm thickness is deposited on the compound semiconductor stacked structure 2 by a plasma CVD method, a sputtering method, or the like. Consequently, the protective insulating film 6 is formed.

The use of SiN for a passivation film covering the compound semiconductor stacked structure 2 can reduce a current collapse.

Subsequently, as illustrated in FIG. 45, an electrode recess 6a is formed in the protective insulating film 6.

In more detail, a resist is first applied on a surface of the protective insulating film 6. The resist is processed by lithography, whereby an opening from which a portion corresponding to a region where to form the gate electrode (planned electrode formation region), in the surface of the protective insulating film 6 is exposed is formed in the resist. Consequently, a resist mask having the opening is formed.

By using this resist mask, the planned electrode formation region of the protective insulating film 6 is dry-etched to be removed until a surface of the cap layer 2e is exposed. Consequently, the electrode recess 6a from which the planned electrode formation region of the surface of the cap layer 2e is exposed is formed in the protective insulating film 6. The electrode recess 6a has a side surface formed in a forward tapered shape, so that its cross section is in a substantially V shape as illustrated. For the dry etching, fluorine-based etching gas used, for instance. This dry etching is required to give as little etching damage as possible to the cap layer 2e, and the dry etching using the fluorine-based vas gives only a small damage to the electron supply layer 2d.

The electrode recess may be formed by wet etching using a fluorine-based solution instead of the dry etching.

Thereafter, the resist mask is removed by ashing using oxygen plasma or by wetting using a chemical solution.

Subsequently, a gate insulating film 7 is formed as illustrated in FIG. 4C.

In more detail, for example, Al₂O₃ as an insulating material is deposited on the protective insulating film 6 so as to cover an inner wall surface of the electrode recess 6a. Al₂O₃ is deposited with an about 2 nm to about 200 nm film thickness, here an about 40 nm film thickness by, for example, an ALD method (Atomic Layer Deposition). Consequently, the gate insulating film 7 is formed.

incidentally, for the deposition of Al₂O₃, a plasma CVD method, a sputtering method, or the like may be used, for instance, instead of the ALD method. Further, instead of depositing Al₂O₃, a nitride or an oxynitride of Al may be used. Besides, to form the gate insulating film, an oxide, a nitride, or an oxynitride of Si, Hf, Zr, Ti, Ta, or H may be deposited, or some appropriately selected therefrom may be deposited in multilayer.

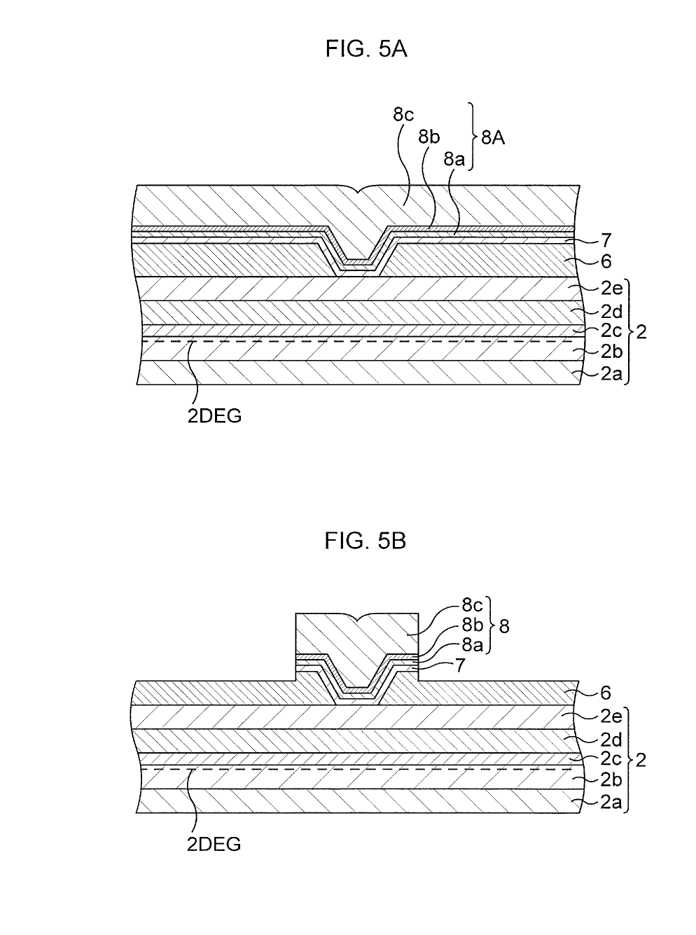

Subsequently, as illustrated in FIG. 5A, an electrode material 8A of the gate electrode is deposited.

In more detail, a TaN:Al layer 8a with an about 40 nm thickness, a TaAlN layer 8b with an about 20 nm thickness, and an Al layer 8c with an about 400 nm thickness are sequentially deposited on the gate insulating film 7 by a sputtering method or the like so as to fill the inside of the electrode recess 6a via the gate insulating film 7. Consequently, the electrode material 8A with a TaN:Al/TaAlN/Al structure is formed. A sputtering target for forming the TaN:Al layer 8a is formed in such a mariner, for example, that Al is brought into contact with TaN and Al is solid-dissolved by heat treatment. A sputtering target for forming the TaAlN layer 8h is made of a compound of TaN and Al. The electrode material 8A is formed. The TaN:Al/TaAlN/Al structure of the electrode material 8A does not necessarily have to be a strictly discriminated layer structure, and near each interface of the layers, they may be in a blended state. Further, an electrode material with a TaN:Cu/TaAlN/Al structure, a TaN:Cu/TaCuN/Al structure, a TaN:Cu/TaCuN/Cu structure, or the like instead of the TaN:Al/TaAlN/Al structure may be formed, for instance.

Subsequently, the gate electrode 8 is formed as illustrated in FIG. 5B.

In more detail, a resist is applied on the electrode material 8A and the resist is processed by lithography, thereby forming a resist mask covering a region where to form the gate electrode on the electrode material 8A.

By using this resist mask, exposed portions of the electrode material 8A are removed by, for example, an ion milling method. At this time, the protective insulating film 6 is slightly over-etched. The resist mask is removed by asking using oxygen plasma or by wetting using a predetermined chemical solution. Consequently, the gate electrode 8 with the TaN:Al/TaAlN/Al structure whose electrode material 8A fills the inside of the electrode recess 6a via the gate insulating film 7 and which has a shape riding on the protective insulating film 6 (with a cross section along a gate length direction being in a so-called overhanging shape) is formed.

Thereafter, through various processes such as the formation of an interlayer insulating film, the formation of wirings connected to the source electrode 4, the drain electrode 5, and the gate electrode 8, the formation of an upper protective film, and the formation of connection electrodes exposed to the uppermost surface, the MIS-type AlGaN/GaN HEMT according to this embodiment is formed.

Regarding the AlGaN/GaN HEMT according to this embodiment, a power-on test was conducted based on comparison with a comparative example. The results will be described below. In an AlGaN/GaN HEMT according to the comparative example, the gate electrode of the AlGaN/GaN HEMT according to this embodiment is formed to have a two-layer structure of a TaN layer and an Al layer as illustrated in FIG. 1A.

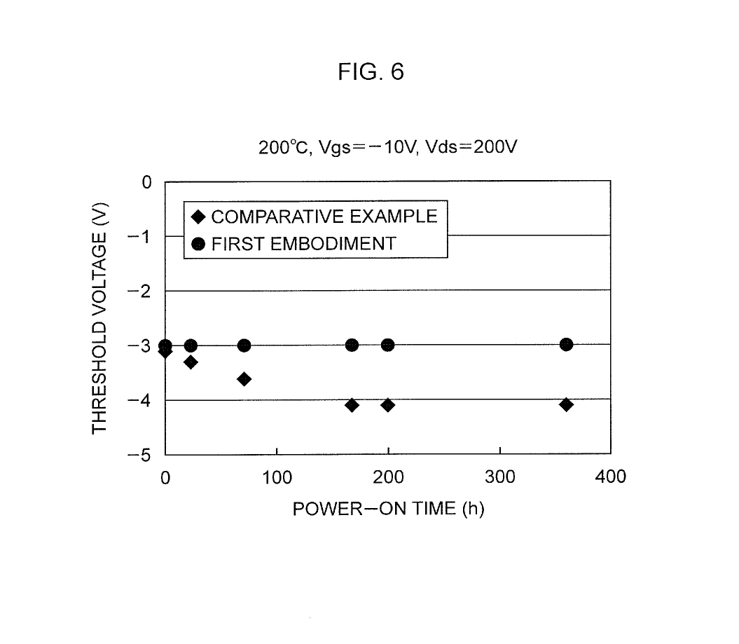

First, a change in a threshold voltage was studied when the power-on test was conducted under a 200° C. environment, with a gate voltage sot to −10 V and a drain voltage set to 200 V. The results are presented in FIG. 6.

In the comparative example, the threshold voltage changes in a negative direction as the power-on time becomes longer. This change is thought to have occurred because, in the gate electrode, Al atoms diffused downward from the Al layer to reach the inside of the TaN layer and further the gate insulating film and a work function of metal in contact with the gate insulating film changed. On the other hand, in this embodiment, a change in the threshold voltage was not recognized even when the power-on time became long. As described above, it has been confirmed that the TaN:Al/TaAlN/Al structure in the gate electrode has high reliability.

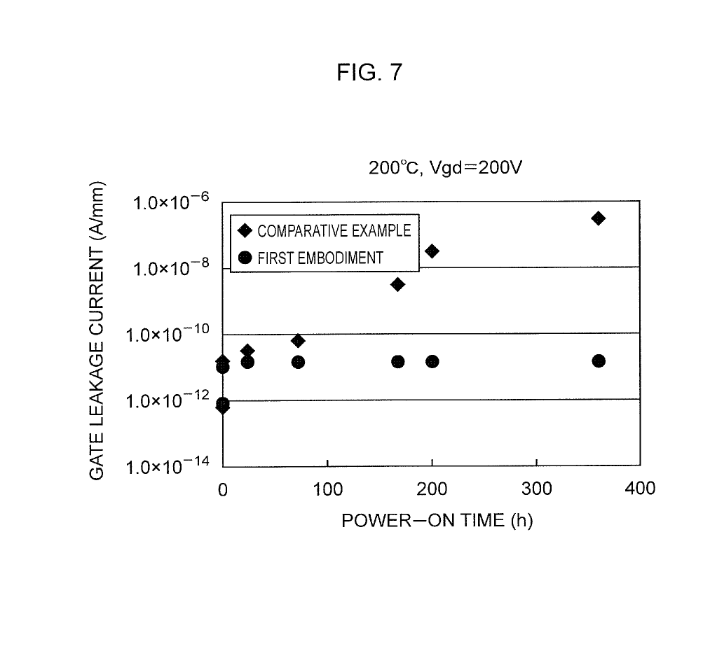

Next, a change in a gate leakage current was studied when the power-on test was conducted at with a gate-drain voltage set to 200 V. The results are presented in FIG. 7.

In the comparative example, the gate leakage current increases as the power-on time becomes longer. This is thought to have occurred because the Al atoms diffused downward from the Al layer in the gate electrode to reach the gate insulating film and a leakage path was generated. On the other hand, in this embodiment, a change in the gate leakage current was not recognized even when the power on time became longer. As described above, it has been confirmed that the TaN:Al/TaAlN/Al structure in the gate electrode of this embodiment has high reliability.

As described above, according to this embodiment, a highly reliable and high-withstand-voltage AlGaN/GaN HEMT including the gate electrode 8 which improves a withstand voltage characteristic and a threshold characteristic is realized.

### Second Embodiment

In this embodiment, a structure and a manufacturing method of an AlGaN/GaN HEMT is disclosed as in the first embodiment, but a Schottky-type AlGaN/GaN HEMT which does not have a gate insulating film and in which a gate electrode is in Schottky-contact with a surface of a compound semiconductor stacked structure is exemplified. Note that the same constituent members and the like as those of the first embodiment will be denoted by the same reference signs and a detailed description thereof will be omitted.

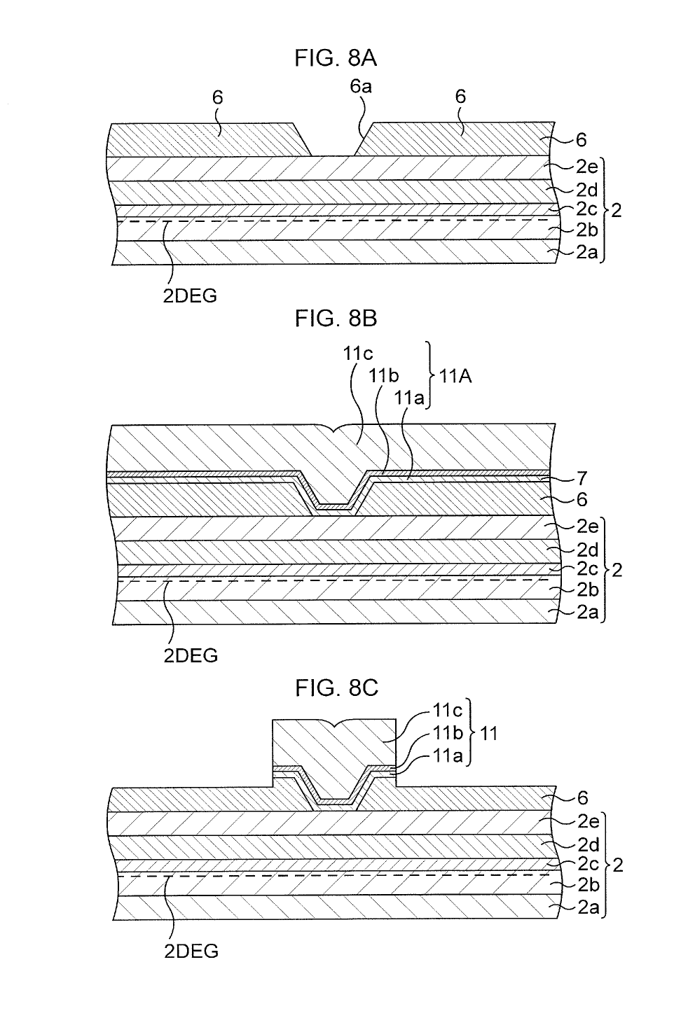

FIG. 8A to FIG. 8C are schematic cross-sectional views illustrating main steps of a method of manufacturing the AlGaN/GaN HEMT according to the second embodiment. In FIG. 8A to FIG. 8C, the vicinity of an electrode recess of a protective insulating film is illustrated in an enlarged manner, and the illustration of a Si substrate, element isolation structures, a source electrode, and a drain electrode is omitted.

In this embodiment, the steps in FIG. 3A to FIG. 4B are first performed as in the first embodiment. At this time, an electrode recess 6a is formed in the protective insulating film 6 on compound semiconductor stacked structure 2 as illustrated in FIG. 8A.

Subsequently, an electrode material 11A of a gate electrode is deposited as illustrated in FIG. 8B.

In more detail, a TaN:Al layer 11a with an about 40 nm thickness, a TaAlN layer 11b with an about 20 nm thickness, and an Al layer 11b with an about 400 nm thickness are sequentially deposited on the protective insulating film 6 by a sputtering method or the like so as to fill the inside of the electrode recess Ga. Consequently, the electrode material 11A with a TaN:Al/TaAlN/Al structure is formed. A sputtering target for forming the TaN:Al layer 11a is formed in such a manner that, for example, Al is brought into contact with TaN, and Al is solid-dissolved by heat treatment. A sputtering target for forming the TaAlN layer 11b is made of a compound of TaN and Al. The electrode material 11A is formed. The TaN:Al/TaAlN/Al structure of the electrode material 11A does not necessarily have to be a strictly discriminated layer structure, and near each interface of the layers, they may be in a blended state. Further, an electrode material with a TaN:Cu/TaAlN/Al structure, a TaN:Cu/TaCuN/Al structure, a TaN:Cu/TaCuN/Cu structure, or the like instead of the TaN:Al/TaAlN/Al structure may be formed, for instance.

Subsequently, a gate electrode 11 is formed as illustrated in FIG. 8C.

In more detail, a resist is applied on the electrode material 11A and the resist is processed by lithography, thereby forming a resist mask covering a region where to form the gate electrode on the electrode material 11A.

By using this resist mask, exposed portions of the electrode material 11A are removed by, for example, an ion milling method. At this time, the protective insulating film 6 is slightly over-etched. The resist mask is removed by ashing using oxygen plasma or by wetting using a predetermined chemical solution. Consequently, the gate electrode 11 with the TaN:Al/TaAlN/Al structure whose electrode material 11A fills the inside of the electrode recess 6a and which has a shape riding on the protective insulating film 6 (with a cross section along a gate length direction being in a so-called overhanging shape; is formed. On a bottom surface of the electrode recess 6a, the gate electrode 11 is in Schottky contact with the surface of the compound semiconductor stacked structure 2 (cap layer 2e).

Thereafter, through various processes such as the formation of an interlayer insulating film, the formation of wirings connected to a source electrode 4, a drain electrode 5, and the gate electrode 11, the formation of an upper protective film, and the formation of connection electrodes exposed to the uppermost surface, the Schottky-type AlGaN/GaN HEMT according to this embodiment is formed.

As described above, according to this embodiment, a highly reliable and high-withstand-voltage AlGaN/GaN HEMT including the gate electrode 11 which improves a withstand voltage characteristic and a threshold characteristic is realized.

### Third Embodiment

In this embodiment, a power supply circuit to which the AlGaN/GaN HEMT of the first or second embodiment is applied is disclosed.

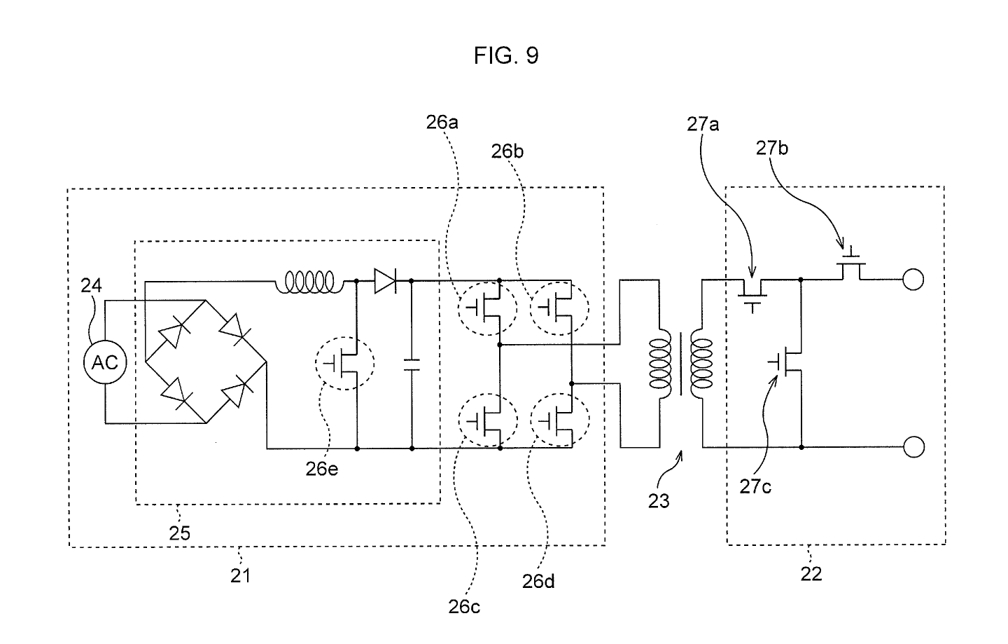

FIG. 9 is a connection diagram illustrating a schematic structure of the power supply circuit according to the third embodiment.

The power supply circuit according to this embodiment includes a high-voltage primary-side circuit 21, a low-voltage secondary-side circuit 22, and a transformer 23 disposed between the primary-side circuit 21 and the secondary-side circuit 22.

The primary-side circuit 21 includes an AC power source 24, a so-called bridge rectifying circuit 25, and a plurality of (four here) switching elements 26a, 26b, 26c, 26d. Further, the bridge rectifying circuit 25 has a switching element 26e.

The secondary-side circuit 22 includes a plurality of (three here) switching elements 27a, 27b, 27c.

In this embodiment, the switching elements 26a, 26b, 26c, 26d, 26e of the primary-side circuit 21 are each the AlGaN/GaN HEMT according to the first or second embodiment. On the other hand, the switching elements 27a, 27b, 27c of the secondary-side circuit 22 are each an ordinary MIS FET using silicon.

According to this embodiment, a highly reliable and high-withstand-voltage AlGaN/GaN HEMT including a gate electrode which improves a withstand voltage characteristic and a threshold characteristic is applied to a power supply circuit. Consequently, a highly reliable and high-power power supply circuit is realized.

### Fourth Embodiment

In this embodiment, a high-frequency amplifier to which the AlGaN/GaN HEMT according to the first or second embodiment is applied is disclosed.

FIG. 10 is a connection diagram illustrating a schematic structure of the high-frequency amplifier according to the fourth embodiment.

The high-frequency amplifier according to this embodiment includes a digital pre-distortion circuit 31, mixers 32a, 32b, and a power amplifier 33.

The digital pre-distortion circuit 31 compensates nonlinear distortion of an input signal. The mixer 32a mixes the input signal whose nonlinear distortion is compensated and an AC signal. The power amplifier 33 amplifies the input signal mixed with the AC signal, and has the AlGaN/GaN HEMT according to the first or second embodiment. In FIG. 10, by, for example, changing of the switches, an output-side signal can be mixed with the AC signal by the mixer 32b, and the resultant can be sent out to the digital pre-distortion circuit 31.

In this embodiment, a highly reliable and high-withstand-voltage AlGaN/GaN HEMT including a gate electrode which improves a withstand voltage characteristic and a threshold characteristic is applied to a high-frequency amplifier.

### Other Embodiments

In the first to fourth embodiments, the AlGaN/GaN HEMT is exemplified as the compound semiconductor device. As the compound semiconductor device, the present invention is applicable to the following HEMTs, besides the AlGaN/GaN HEMT.

### Example 1 of Other HEMT

In this example, an InAlN/GaN HEMT is disclosed as the compound semiconductor device.

InAlN and GaN are compound semiconductors whose lattice constants can be made close to each other by the composition. In this case, in the above-described first to fourth embodiments, the electron transit layer is made of i-GaN, the intermediate layer is made of i-InAlN, the electron supply layer is made of n-InAlN, and the cap layer is made of n-GaN. Further, in this case, almost no piezoelectric polarization occurs, and therefore, two-dimensional electron gas is generated mainly by spontaneous polarization of InAlN.

According to this example, a highly reliable and high-withstand-voltage InAlN/GaN HEMT including a gate electrode which improves a withstand voltage characteristic and a threshold characteristic is realized similarly to the above-described AlGaN/GaN HEMT.

### Example 2 of Other HEMT

In this example, an InAlGaN/GaN HEMT is disclosed as the compound semiconductor device.

GaN and InAlGaN are compound semiconductors, with the latter capable of having a smaller lattice constant than that of the former by the composition. In this case, in the above-described first to fourth embodiments, the electron transit layer is made of i-GaN, the intermediate layer is made of i-InAlGaN, the electron supply layer is made of n-InAlGaN, and the cap layer is made of n-GaN.

According to this example, a highly reliable and high-withstand-voltage InAlGaN/GaN HEMT including a gate electrode which improves a withstand voltage characteristic and a threshold characteristic is realized similarly to the above-described AlGaN/GaN HEMT.

According to the above-described various embodiments, a highly reliable and high-withstand-voltage compound semiconductor device including an electrode which improves a withstand voltage characteristic and a threshold characteristic is realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spin and scope of the invention.

What is claimed is:

1. A compound semiconductor device comprising:
a compound semiconductor stacked structure; and
an electrode formed above the compound semiconductor stacked structure, the electrode comprising:
a first electrode layer having a first low-resistance metal; and
a second electrode layer disposed between the compound semiconductor stacked structure and the first electrode layer and having a first nitride conductor in which a second low-resistance metal is solid-dissolved.

2. The compound semiconductor device according to claim 1, wherein the electrode further comprises a third electrode layer disposed between the first electrode layer and the second electrode layer and having a compound of a second nitride conductor and a third low-resistance metal.

3. The compound semiconductor device according to claim 1, wherein the first low-resistance metal and the second low-resistance metal are the same.

4. The compound semiconductor device according to claim 1, wherein the first nitride conductor and the second nitride conductor are the same.

5. The compound semiconductor device according claim 1, further comprising
a protective insulating film formed on the compound semiconductor stacked structure and having an opening whose side surface is in a forward tapered shape,
wherein the electrode fills an inside of the opening and is formed on the protective insulating film.

6. A method of manufacturing a compound semiconductor device comprising:
forming a compound semiconductor stacked structure; and
forming an electrode above the compound semiconductor stacked structure, the electrode comprising:
a first electrode layer having a first low-resistance metal; and
a second electrode layer disposed between the compound semiconductor stacked structure and the first electrode layer and having a first nitride conductor in which a second low-resistance metal is solid-dissolved.

7. The method of manufacturing the compound semiconductor device according to claim 6, wherein the electrode further comprises a third electrode layer disposed between the first electrode layer and the second electrode layer and having a compound of a second nitride conductor and a third low-resistance metal.

8. The method of manufacturing the compound semiconductor device according to claim 6, wherein the first low-resistance metal and the second low-resistance metal are the same.

9. The method of manufacturing the compound semiconductor device according to claim 6, wherein the first nitride conductor and the second nitride conductor are the same.

10. The method of manufacturing the compound semiconductor device according to claim 6, further comprising
forming a protective insulating film having an opening whose side surface is in a forward tapered shape, on the compound semiconductor stacked structure,
wherein the electrode fills an inside of the opening and is formed on the protective insulating film.

11. A power supply circuit comprising:
a transformer; and
a high-voltage circuit and a low-voltage circuit sandwiching the transformer, the high-voltage circuit comprising
a transistor; the transistor comprising:
a compound semiconductor stacked structure; and
an electrode formed above the compound semiconductor stacked structure, the electrode comprising:
a first electrode layer having a first low-resistance metal; and
a second electrode layer disposed between the compound semiconductor stacked structure and the first electrode layer and having a first nitride conductor in which a second low-resistance metal is solid-dissolved.
